(19) United States
(12) Patent Application Publication
(10) Pub. No.: US 2025/0140613 A1
(43) Pub. Date: May 1, 2025

(54) METHOD OF PROCESSING WAFER

(71) Applicant: DISCO CORPORATION, Tokyo (JP)

(72) Inventor: Tsubasa HIROSE, Tokyo (JP)

(21) Appl. No.: 18/910,140

(22) Filed: Oct. 9, 2024

(30) Foreign Application Priority Data
Nov. 1, 2023 (JP) 2023-187596

(51) Int. Cl. H01L 21/78; B23K 26/53; B23K 101/40; B23K 103/00; H01L 21/268

(52) U.S. Cl. CPC H01L 21/78; B23K 26/53; H01L 21/268; B23K 2101/40; B23K 2103/56

(57) ABSTRACT

A method of processing a wafer includes a first processing step of forming shield tunnels, each including a pore and a modified layer surrounding the pore, in the wafer by applying a first laser beam within the wafer in alignment with each of projected dicing lines, applying a second laser beam having a power output stronger than that of the first laser beam while positioning a focused spot thereof within the wafer in alignment with each of the projected dicing lines, at intervals smaller than intervals at which the shield tunnels have been formed in the wafer, thereby inducing cracks in the wafer along each of the projected dicing lines, and dividing the wafer into individual device chips by applying an external force to the wafer.

### BACKGROUND OF THE INVENTION

### Field of the Invention

The present invention relates to a method of processing a wafer with a plurality of devices formed in respective areas demarcated on a face side thereof by a grid of projected dicing lines, to thereby divide the wafer into individual device chips that include the respective devices.

### Description of the Related Art

Wafers each with a plurality of devices such as integrated circuits (ICs) and large-scale integration (LSI) circuits formed in respective areas demarcated on its face side by a grid of projected dicing lines are divided by a laser processing apparatus into individual device chips that include the respective devices. The device chips will be incorporated in electronic appliances such as cellular phones and personal computers, for example.

The laser processing apparatus includes a chuck table for holding a wafer thereon, a laser beam applying unit for applying a laser beam having a wavelength transmittable through the wafer to the wafer held on the chuck table while positioning a focused spot of the laser beam within the wafer along one at a time of the projected dicing lines, and a feed mechanism for processing-feeding the chuck table and the laser beam applying unit relative to each other. It has been known in the art that, under laser processing conditions appropriately established to process the wafer with the laser beam, the laser processing apparatus operates to form shield tunnels to a nicety within the wafer along the projected dicing lines, each of the shield tunnels including a pore acting as a division initiating point and a modified layer surrounding the pore (see, for example, Japanese Patent Laid-open No. 2014-221483).

Wafers from which to fabricate light emitting diodes (LEDs) or electronic power devices, for example, include a substrate made of a hard material such as SiC, GaN, diamond, or sapphire. Therefore, for forming modified layers, which are to be used as division initiating points, within those wafers, it is necessary to apply a laser beam having a relatively strong power output level to the wafers.

### SUMMARY OF THE INVENTION

However, after modified layers have been formed in a hard wafer along projected dicing lines by a high-power laser beam, large external forces or loads need to be imposed on the wafer for dividing the wafer into individual device chips. In addition, it has been difficult or impossible to accurately control the lines along which to actually divide the wafer under the applied external forces, tending to break off chippings or fragments from the outer circumference of the wafer that may possibly lower the quality of device chips fabricated from the wafer.

It is therefore an object of the present invention to provide a method of processing a wafer in a manner to reduce loads imposed on the wafer at the time the wafer is divided into individual device chips and prevent the wafer from producing chippings at its outer circumference.

In accordance with an aspect of the present invention, there is provided a method of processing a wafer with a plurality of devices formed in respective areas demarcated on a face side thereof by a grid of projected dicing lines, to thereby divide the wafer into individual device chips that include the respective devices, the method including a first processing step of forming shield tunnels, each including a pore and a modified layer surrounding the pore, in the wafer by applying a first laser beam having a wavelength transmittable through the wafer while positioning a focused spot of the first laser beam within the wafer in alignment with each of the projected dicing lines, a second processing step of forming a modified layer in the wafer along each of the projected dicing lines by applying a second laser beam having a wavelength transmittable through the wafer and a power output stronger than that of the first laser beam while positioning a focused spot of the second laser beam within the wafer in alignment with each of the projected dicing lines, at intervals smaller than intervals at which the shield tunnels have been formed in the wafer, thereby inducing cracks in the wafer and exposing the cracks on the face side of the wafer along each of the projected dicing lines, and a dividing step of dividing the wafer into individual device chips by applying an external force to the wafer.

Preferably, the first processing step includes forming a plurality of layers of shield tunnels stacked in thicknesswise directions of the wafer along each of the projected dicing lines. Preferably, the first processing step and the second processing step include applying the first laser beam and the second laser beam, respectively, to the face side of the wafer. Preferably, the wafer includes a substrate made of a material selected from a group consisting of SiC, GaN, diamond, and sapphire.

With the method of processing a wafer according to the aspect of the present invention, the cracks that are relatively large and extend straight, not tortuously, along the projected dicing lines have been formed in the wafer before the dividing step. Therefore, a load applied to the wafer to apply external forces thereto in the dividing step may be relatively small in dividing the wafer precisely into the individual device chips without causing the wafer to break off chippings or fragments.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a laser processing apparatus that is used to carry out a method of processing a wafer, also referred to as a wafer processing method, according to an embodiment of the present invention;

FIG. 2 is a perspective view of a frame unit including a wafer to be processed by the laser processing apparatus;

FIG. 3 is a perspective view illustrating a manner in which a first processing step of the wafer processing method is performed on the wafer;

FIG. 4A is an enlarged fragmentary cross-sectional view of the wafer in which a first layer of shield tunnels is formed in the first processing step;

FIG. 4B is an enlarged conceptual perspective view of one of the shield tunnels formed in the first processing step illustrated in FIG. 4A;

FIG. 5A is a perspective view illustrating a manner in which a second processing step of the wafer processing method is performed on the wafer;

FIG. 5B is an enlarged fragmentary cross-sectional view of the wafer in which a modified layer and cracks are formed in the second processing step illustrated in FIG. 5A;

FIG. 5C is a perspective view of the frame unit including the wafer in which the cracks are formed in the second processing step;

FIG. 6A is an enlarged fragmentary cross-sectional view of the wafer in which a second layer of shield tunnels is formed in a modification of the first processing step;

FIG. 6B is an enlarged fragmentary cross-sectional view of the wafer in which a third layer of shield tunnels is formed subsequently to the second layer of shield tunnels illustrated in FIG. 6A;

FIG. 6C is an enlarged fragmentary cross-sectional view of the wafer in which a fourth layer of shield tunnels is formed subsequently to the third layer of shield tunnels illustrated in FIG. 6B and cracks are exposed on a face side of the wafer;

FIG. 7A is an enlarged fragmentary cross-sectional view illustrating a manner in which the second processing step is performed on the wafer after the layers of shield tunnels have been formed in the wafer in the modification of the first processing step;

FIG. 7B is a perspective view of the frame unit including the wafer in which the cracks are formed in the second processing step illustrated in FIG. 7A; and

FIG. 8 is a cross-sectional view illustrating a manner in which a dividing step of the wafer processing method is carried out.

### DETAILED DESCRIPTION OF THE PREFERRED EMBODIMENT

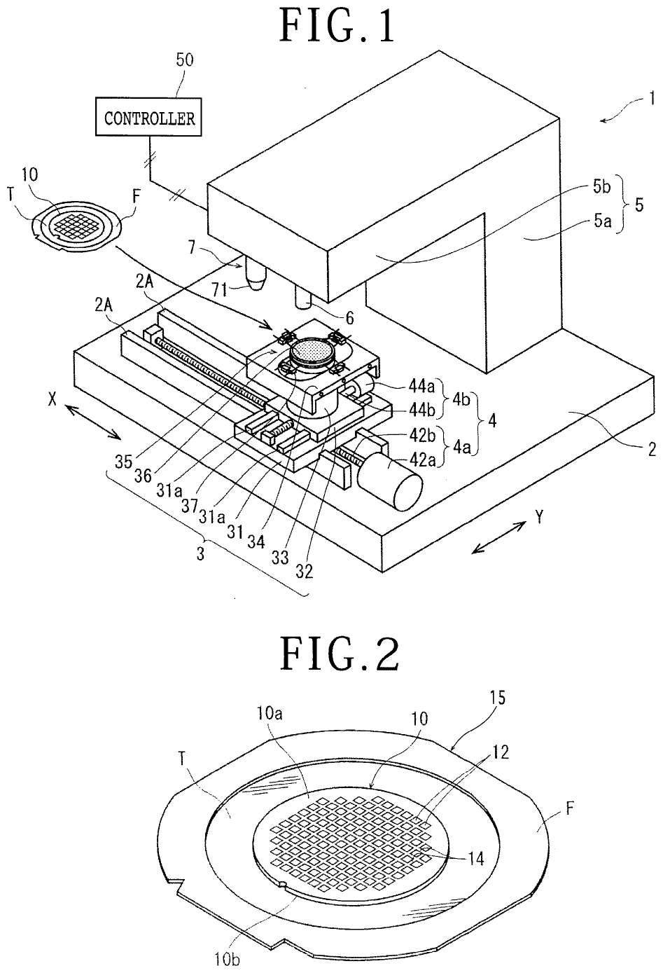

A method of processing a wafer, also referred to as a wafer processing method, according to a preferred embodiment of the present invention will be described in detail below with reference to the accompanying drawings. FIG. 1 illustrates in perspective a laser processing apparatus 1 that is used to carry out the wafer processing method according to the present embodiment. As illustrated in FIG. 1, the laser processing apparatus 1 includes at least a base 2, a holding unit 3 mounted on the base 2 for holding a wafer 10 as a workpiece to be processed, and a laser beam applying unit 7 for applying a laser beam to the wafer 10 held on the holding unit 3. FIG. 2 illustrates the wafer 10 in perspective. As illustrated in FIG. 2, the wafer 10 includes a circular substrate of SiC and has a plurality of devices 12 formed in respective areas demarcated on a face side 10a thereof by a grid of projected dicing lines 14. The wafer 10 has a thickness of approximately 500 μm. The wafer 10 has a reverse side 10b affixed to a central region of an adhesive tape T that has a peripheral region affixed to an annular frame F. The wafer 10, the adhesive tape T, and the annular frame F are thus integrally combined into a frame unit 15. In the frame unit 15, the wafer 10 is supported on the annular frame F by the adhesive tape T.

As illustrated in FIG. 1, the laser processing apparatus 1 further includes an alignment unit 6 for performing alignment for aligning the wafer 10 with the laser beam applying unit 7 on the basis of an image captured of the wafer 10 held on the holding unit 3, a moving assembly 4 for moving the holding unit 3 with respect to the laser beam applying unit 7, a frame block 5 including a vertical wall 5a erected on the base 2 sideways of the moving assembly 4 and a horizontal beam 5b extending horizontally from an upper end portion of the vertical wall 5a in overhanging relation to the holding unit 3, a controller 50, and a display unit, not depicted.

The holding unit 3 includes a rectangular X-axis movable plate 31 movably mounted on the base 2 for movement along a horizontal X-axis indicated by an arrow X, a rectangular Y-axis movable plate 32 movably mounted on the X-axis movable plate 31 for movement along a horizontal Y-axis indicated by an arrow Y that extends perpendicularly to the X-axis, a hollow cylindrical support post 33 fixedly mounted on an upper surface of the Y-axis movable plate 32, and a rectangular cover plate 34 fixedly mounted on an upper end of the support post 33. The cover plate 34 has an oblong hole defined therein and extending vertically therethrough. A chuck table 35 extends upwardly through the oblong hole in the cover plate 34. The chuck table 35 supports on its upper surface a circular suction chuck 36 that is made of an air-permeable porous material and that has an upper surface acting as a holding surface of the chuck table 35. The holding surface lies along a horizontal XY plane defined by the X-axis and the Y-axis and hence can be identified by coordinates along the X-axis and the Y-axis. The suction chuck 36 is fluidly connected to suction means, not depicted, through a fluid channel, not depicted, defined in and extending through the support post 33. The suction chuck 36 is surrounded by four angularly equally spaced clamps 37 that are used to grip the annular frame F that supports the wafer 10 held on the chuck table 35. When the suction means is actuated, it generates and applies a negative pressure through the fluid channel to the holding surface of the suction chuck 36, thereby holding the wafer 10 under suction on the holding surface.

The moving assembly 4 includes an X-axis moving mechanism 4a mounted on the base 2 for moving the chuck table 35 along the X-axis, a Y-axis moving mechanism 4b mounted on the Y-axis movable plate 32 for moving the chuck table 35 along the Y-axis, and a rotating mechanism, not depicted, housed in the support post 33 for rotating the chuck table 35 about its vertical central axis. The X-axis moving mechanism 4a converts rotary motion of an electric motor 42a into linear motion through a ball screw 42b and transmits the linear motion to the X-axis movable plate 31 to move the X-axis movable plate 31 along the X-axis along a pair of guide rails 2A mounted on the base 2 and extending along the X-axis. The Y-axis moving mechanism 4b converts rotary motion of an electric motor 44a into linear motion through a ball screw 44b and transmits the linear motion to the Y-axis movable plate 32 to move the Y-axis movable plate 32 along the Y-axis along a pair of guide rails 31a mounted on the X-axis movable plate 31 and extending along the Y-axis.

The horizontal beam 5b of the frame block 5 houses therein an optical system of the laser beam applying unit 7 and the alignment unit 6. The laser beam applying unit 7 includes a beam condenser 71 including a condensing lens, not depicted, for converging a laser beam and applying the converged laser beam to the wafer 10 on the suction chuck 36. The beam condenser 71 is disposed on a lower surface of a distal end portion, remote from the vertical wall 5a, of the horizontal beam 5b.

The alignment unit 6 includes image capturing means for capturing an image of the wafer 10 held by the holding unit 3 and detecting a position on the wafer 10 where the laser beam is to be applied. The alignment unit 6 is able to detect the height of the face side 10a of the wafer 10 with respect to the suction chuck 36 that provides the holding surface of the chuck table 35, i.e., the thickness of the wafer 10. The alignment unit 6 is disposed in a position adjacent to the beam condenser 71 along the X-axis.

The controller 50, which includes a computer, includes a central processing unit (CPU) for performing arithmetic processing operations according to control programs, a read only memory (ROM) for storing the control programs and other data, a readable and writable random access memory (RAM) for temporarily storing detected values and calculated results, for example, an input interface, and an output interface. Details of the hardware of the controller 50 are omitted from illustration as they are well known in the art. The moving assembly 4, the alignment unit 6, the laser beam applying unit 7, a non-illustrated display unit, and the like are electrically connected to the controller 50. The repetitive frequency and average power output of the laser beam applied by the laser beam applying unit 7 are adjusted as appropriate by the controller 50. Image data captured by the alignment unit 6 are stored in an appropriate memory of the controller 50.

The display unit displays captured image data and laser processing conditions, for example.

The laser processing apparatus 1 that carries out the wafer processing method according to the present embodiment is arranged roughly as described above. The wafer processing method according to the present embodiment that is performed by the laser processing apparatus 1 to divide the wafer 10 into individual device chips will now be described in detail below.

### First Processing Step

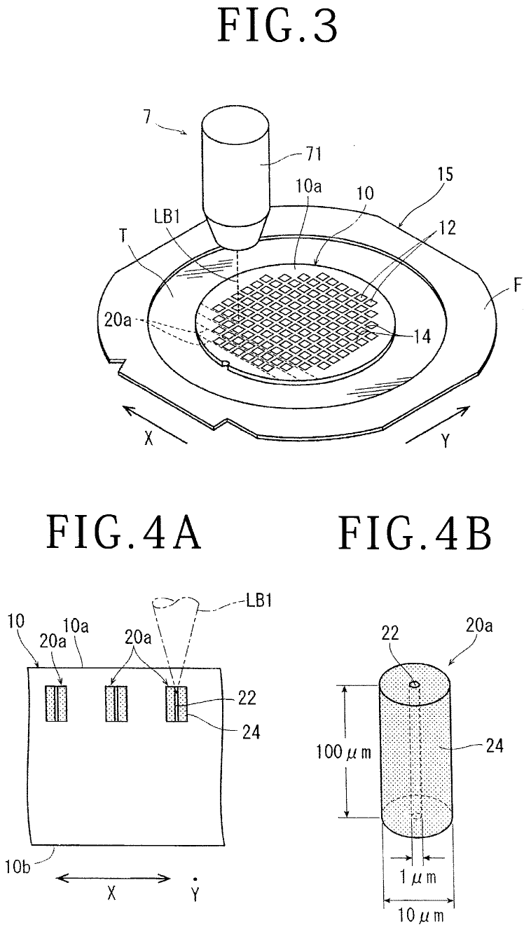

In the wafer processing method according to the present embodiment, a first processing step is initially carried out to apply a first laser beam LB1 (see FIG. 3) having a wavelength transmittable through the wafer 10 to the face side 10a of the wafer 10 while the first laser beam LB1 is having a focused spot positioned in the wafer 10 in alignment with one of the projected dicing lines 14, thereby forming a shield tunnel including a pore and an amorphous modified layer surrounding the pore in the wafer 10.

For carrying out the first processing step, the frame unit 15 with the wafer 10 to be processed is taken out of a cassette, not depicted, that stores a plurality of frame units 15 therein, and then the wafer 10 of the frame unit 15 is placed and held under suction on the suction chuck 36 on the chuck table 35, with the annular frame F gripped in position by the clamps 37.

Then, the moving assembly 4 is actuated to move the wafer 10 to a position directly below the alignment unit 6. The alignment unit 6 then captures an image of the face side 10a of the wafer 10. The controller 50 controls the moving assembly 4 to adjust the position of the wafer 10 to align the projected dicing lines 14 that are oriented in a first direction with the X-axis. The alignment unit 6 identifies the coordinates along the X-axis and the Y-axis of one of the projected dicing lines 14 along which the wafer 10 is to be processed, and detects the height of the face side 10a of the wafer 10. The identified coordinates and the detected height are stored in the appropriate memory of the controller 50.

Then, the controller 50 actuates the X-axis moving mechanism 4a and the Y-axis moving mechanism 4b on the basis of the information detected by the alignment unit 6, moving one of the projected dicing lines 14 oriented in the first direction to a position directly below the beam condenser 71 of the laser beam applying unit 7. Then, the controller 50 actuates a focused spot position adjusting unit, not depicted, to position the focused spot of the first laser beam LB1 in the wafer 10 beneath the projected dicing line 14 at a predetermined thicknesswise position, i.e., at a predetermined depth, in the wafer 10. In the first processing step, the predetermined thicknesswise position where the focused spot of the first laser beam LB1 is positioned in the wafer 10 lies in the vicinity of the face side 10a of the wafer 10, as illustrated in FIG. 4A.

After the focused spot of the first laser beam LB1 has been positioned as described above, the controller 50 energizes the laser beam applying unit 7 to emit the first laser beam LB1 from the beam condenser 71 and apply the first laser beam LB1 to the wafer 10, and actuates the X-axis moving mechanism 4a to move, i.e., processing-feed, the wafer 10 along the X-axis, forming a first layer of shield tunnels 20a that are spaced at predetermined intervals along the X-axis. Each of the shield tunnels 20a includes a pore and a modified layer shielding the pore in surrounding relation thereto, in the wafer 10 along the projected dicing line 14, as illustrated in FIGS. 3 and 4A. The projected dicing line 14 along which the wafer 10 has been processed to form the shield tunnels 20a therein by the first laser beam LB1 may be referred to as a “processed projected dicing line 14.” The projected dicing lines 14 along which the wafer 10 has not yet been processed to form shield tunnels 20a therein by the first laser beam LB1 may be referred to as an “unprocessed projected dicing line 14.” As illustrated in FIG. 4B, each of the shield tunnels 20a includes a central pore 22 having a diameter of approximately 1 μm and an amorphous modified layer 24 surrounding the central pore 22 and having a diameter of 10 μm. The shield tunnels 20a have their upper ends spaced from the face side 10a of the wafer 10 by a predetermined distance of approximately 50 μm, for example. Therefore, the shield tunnels 20a are not exposed on the face side 10a of the wafer 10, and cracks that are developed in the wafer 10 from the shield tunnels 20a are not exposed on the face side 10a.

In order to properly form the shield tunnels 20a in the wafer 10, it is important, as described in Japanese Patent Laid-open No. 2014-221483 referred to in the description of the related art, to establish a value (NA/N) calculated by dividing a numerical aperture (NA) of a condensing lens, not depicted, included in the beam condenser 71 by a refractive index (N) of a substrate, made of SiC according to the present embodiment, of the wafer 10, in such a manner as to fall within a range of 0.05 to 0.2.

After the shield tunnels 20a have been formed in the wafer 10 along the processed projected dicing line 14, the controller 50 controls the Y-axis moving mechanism 4b to move, i.e., indexing-feed, the wafer 10 along the Y-axis by the distance between adjacent two of the projected dicing lines 14 until an adjacent one of the projected dicing lines 14, i.e., an unprocessed projected dicing line 14, oriented in the first direction is positioned directly below the beam condenser 71. Then, in the same manner as described above, the first laser beam LB1 is applied to the wafer 10 while positioning its focused spot within the wafer 10 in the vicinity of the face side 10a of the wafer 10 below the unprocessed projected dicing line 14. At the same time, the wafer 10 is moved, i.e., processing-fed, along the X-axis, forming another first layer of shield tunnels 20a in the wafer 10 along the unprocessed projected dicing line 14. The above processing is repeated to apply the first laser beam LB1 to the wafer 10 with the laser beam applying unit 7 and move the wafer 10 along the X-axis and the Y-axis with the X-axis moving mechanism 4a and the Y-axis moving mechanism 4b until first layers of shield tunnels 20a are formed in the wafer 10 along all the projected dicing lines 14 oriented in the first direction.

Thereafter, the controller 50 controls the rotating mechanism to turn the wafer 10 about its central axis through 90 degrees to align the unprocessed projected dicing lines 14 that are oriented in a second direction, which extend perpendicularly to the processed projected dicing lines 14 oriented in the first direction, with the X-axis. Then, the above processing described with respect to the processed projected dicing lines 14 oriented in the first direction is repeated to apply the first laser beam LB1 to the wafer 10 and move the wafer 10 along the X-axis and the Y-axis until first layers of shield tunnels 20a are formed in the wafer 10 along all the unprocessed projected dicing lines 14 oriented in the second direction. In this manner, the first layers of shield tunnels 20a are formed in the wafer 10 along all the projected dicing lines 14 established on the face side 10a of the wafer 10.

Laser processing conditions, hereinafter referred to as “first laser processing conditions,” for forming the first layer of shield tunnels 20a in the wafer 10 near the face side 10a thereof in the first processing step are established by way of example as follows:
Wavelength: 1064 nm
Repetitive frequency: 1 kHz
Average power output: 0.25 W
Processing-feed speed: 25 mm/s

When the first layer of shield tunnels 20a is formed in the wafer 10 near the face side 10a by the first laser beam LB1 under the above first laser processing conditions, the shield tunnels 20a have a height of approximately 100 μm along thicknesswise directions of the wafer 10. As adjacent two of the shield tunnels 20a along the X-axis have their centers spaced 25 μm from each other due to the repetitive frequency and the processing-feed speed referred to above, a distance of approximately 15 μm is present between the adjacent two of the shield tunnels 20a. Moreover, since the average power output is of a relatively weak level of 0.25 W in the above first laser processing conditions, no cracks are developed in the face side 10a of the wafer 10 along the projected dicing lines 14. The first processing step is now completed.

According to the present invention, the first processing step is not limited to the above-described details of the embodiment and may cover a modification in which a plurality of layers of shield tunnels are stacked in the thicknesswise directions of the wafer 10 below the projected dicing lines 14. Such a modification of the first processing step will be described in detail later.

### Second Processing Step

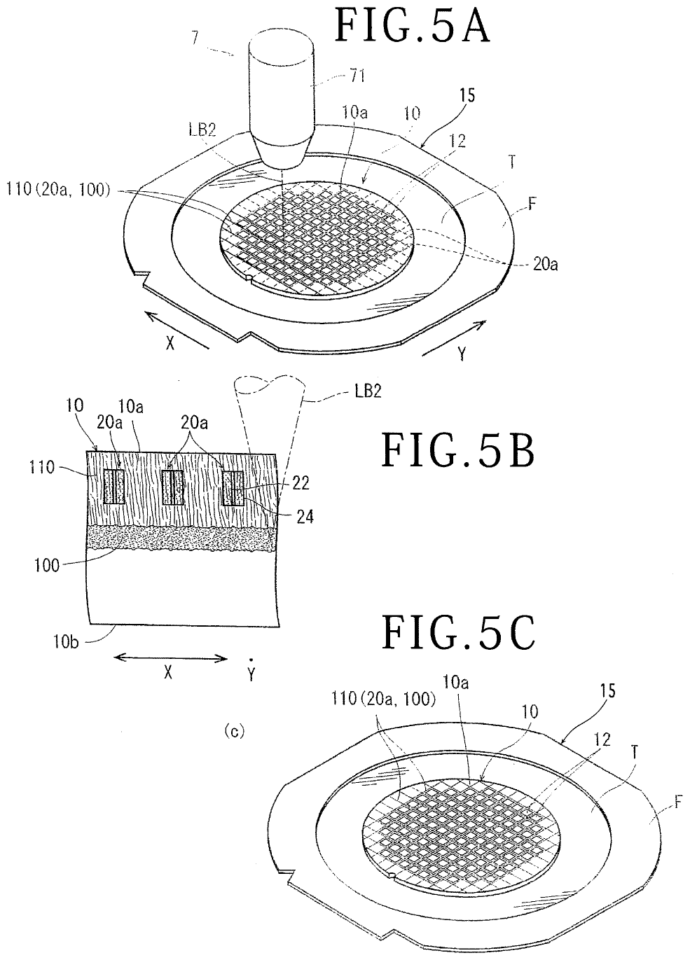

After the first processing step described above, a second processing step is carried out to apply a second laser beam LB2 (see FIG. 5A) having a wavelength transmittable through the wafer 10 and a power output higher than that of the first laser beam LB1 to the wafer 10 while the second laser beam LB2 is having a focused spot positioned in the wafer 10 in alignment with one of the projected dicing lines 14, at spaced intervals smaller than those of the shield tunnels 20a formed in the first processing step, thereby forming a modified layer 100 (see FIG. 5B) in the wafer 10 along the projected dicing line 14. The second processing step will be described in specific detail below.

For carrying out the second processing step, one of the projected dicing lines 14 oriented in the first direction, with the shield tunnels 20a formed in the wafer 10 therealong, is positioned directly below the beam condenser 71 of the laser beam applying unit 7. The laser beam applying unit 7 is controlled by the controller 50 to emit the second laser beam LB2 whose wavelength is transmittable through the wafer 10 and whose power output is higher than that of the first laser beam LB1. In the second processing step, as illustrated in FIG. 5B, the focused spot of the second laser beam LB2 is positioned at a position deeper than the first layer of shield tunnels 20a formed in the first processing step, e.g., at a substantially middle position in the thicknesswise directions of the wafer 10.

Then, the controller 50 energizes the laser beam applying unit 7 to emit the second laser beam LB2 from the beam condenser 71 and apply the second laser beam LB2 to the wafer 10, and actuates the X-axis moving mechanism 4a to move, i.e., processing-feed, the wafer 10 along the X-axis, forming a modified layer 100 in the wafer 10 along the projected dicing line 14, as illustrated in FIG. 5B. The second laser beam LB2 is applied at intervals of 1 μm, for example, smaller than the intervals at which the first layers of shield tunnels 20a have been formed in the wafer 10. Therefore, the modified layer 100 is formed more densely than the shield tunnels 20a.

Thereafter, the controller 50 energizes the laser beam applying unit 7 to apply the second laser beam LB2 to the wafer 10 and also actuates the X-axis moving mechanism 4a, the Y-axis moving mechanism 4b, and the rotating mechanism to form modified layers 100 in the wafer 10 along all the projected dicing lines 14 established on the wafer 10.

Laser processing conditions, hereinafter referred to as “second laser processing conditions,” in the second processing step are established by way of example as follows:
Wavelength: 1064 nm
Repetitive frequency: 25 kHz
Average power output: 7.3 W
Processing-feed speed: 25 mm/s

In the second processing conditions, the processing-feed speed remains the same value of 25 mm/s as the processing-feed speed in the first processing step, and the repetitive frequency is of a larger value than the repetitive frequency in the first processing step. In addition, the average power output of the second laser beam LB2 is of a value of 7.3 W that is higher than the average power output of the first laser beam LB1. When the modified layer 100 is continuously formed in the wafer 10 along the projected dicing line 14, as illustrated in FIG. 5B, the first layer of shield tunnels 20a is expanded, inducing cracks 110 in the wafer 10 along the projected dicing line 14 and exposing the cracks 110 on the face side 10a, as illustrated in FIG. 5C. The cracks 110 extend straight, rather than tortuously, along the projected dicing line 14, and are of a relatively large size starting from the modified layer 100 and developed via the shield tunnels 20a to the face side 10a. Thereafter, the second laser beam LB2 is applied to the wafer 10 and the wafer 10 is moved along the X-axis and the Y-axis until modified layers 100 are formed in the wafer 10 along all the unprocessed projected dicing lines 14 established on the wafer 10.

According to the present embodiment, the modified layers 100 are formed in the wafer 10 along the projected dicing lines 14 by the second laser beam LB2 that is applied at spaced intervals smaller than those of the shield tunnels 20a formed in the first processing step and that has its repetitive frequency set to a larger value, as described above. However, the present invention is not limited to such details. The modified layers 100 may be formed in the wafer 10 along the projected dicing lines 14 by reducing the processing-feed speed at which the wafer 10 is moved along the X-axis by the X-axis moving mechanism 4a or adjusting both the processing-feed speed and the repetitive frequency. For applying the second laser beam LB2 to the wafer 10, the value (NA/N) calculated by dividing the numerical aperture (NA) of the condensing lens, not depicted, included in the beam condenser 71 by the refractive index (N) of the substrate, made of SiC, of the wafer 10 may not fall within the range of 0.05 to 0.2. Therefore, the second processing step may be carried out by another laser processing apparatus including a beam condenser different from the beam condenser 71 of the laser processing apparatus 1.

The present invention is not limited to the embodiment described above. As described above, the first processing step according to the present invention may cover a modification described below, for example. According to the modification, in addition to the first layer of shield tunnels 20a formed in the wafer 10 in the first processing step under the first processing conditions, as illustrated in FIG. 4A, other layers of shield tunnels are formed in the wafer 10 at a position deeper than the first layer of shield tunnels 20a in the thicknesswise directions of the wafer 10 along the projected dicing lines 14.

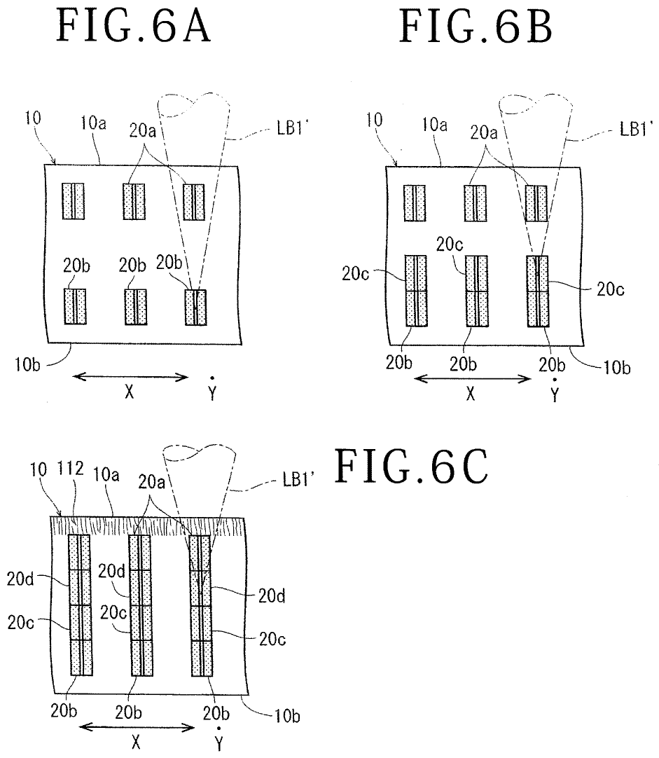

Specifically, in the first processing step, after the first layers of shield tunnels 20a have been formed in the vicinity of the face side 10a of the wafer 10, a first laser beam LB1′ is applied to the wafer 10 under the first processing conditions while positioning its focused spot in the wafer 10 near the reverse side 10b of the wafer 10 as illustrated in FIG. 6A, and the X-axis moving mechanism 4a is actuated to move the wafer 10 along the X-axis, forming a second layer of shield tunnels 20b in the wafer 10 in the vicinity of the reverse side 10b along one of the projected dicing lines 14 oriented in the first direction. As with the shield tunnels 20a, each of the shield tunnels 20b includes a pore and an amorphous modified layer shielding the pore in surrounding relation thereto. The shield tunnels 20b have their lower ends spaced from the reverse side 10b of the wafer 10 by a predetermined distance of approximately 50 μm, for example.

Then, the moving assembly 4 is actuated in the same fashion as it was actuated to form the first layers of shield tunnels 20a in the wafer 10 in the first processing step, and the first laser beam LB1′ is applied to the wafer 10 to form second layers of shield tunnels 20b therein along all the projected dicing lines 14 established on the wafer 10. The condensing lens used to emit the first laser beam LB1′ to form the second layers of shield tunnels 20b in the wafer 10 should satisfy the same conditions as the condensing lens used to emit the first laser beam LB1 to form the first layers of shield tunnels 20a in the wafer 10.

Although laser processing conditions for forming the second layers of shield tunnels 20b in the wafer 10 may be the same as the first processing conditions referred to above, they should preferably be different from the first processing conditions in that the average power output is slightly stronger than the average power output in the first processing conditions. Such slightly different laser processing conditions, hereinafter referred to as “third laser processing conditions,” are established by way of example as follows:
Wavelength: 1064 nm
Repetitive frequency: 1 kHz
Average power output: 0.5 W
Processing-feed speed: 25 mm/s

Since the repetitive frequency and the processing-feed speed in the third processing conditions are the same as those in the first processing conditions, adjacent two of the shield tunnels 20b are spaced from each other by an interval that is the same as the interval by which adjacent two of the shield tunnels 20a are spaced from each other. Adjacent two of the shield tunnels 20b are spaced from each other, and the first layers of shield tunnels 20a and the second layers of shield tunnels 20b are spaced from each other in the thicknesswise directions of the wafer 10. Further, inasmuch as the average power output of the first laser beam LB1′ is lower than the average power output of the second laser beam LB2 applied in the second processing step to be described later, cracks are not exposed on the face side 10a and the reverse side 10b of the wafer 10 when the second layers of shield tunnels 20b are formed in the wafer 10.

According to the present modification, after the second layers of shield tunnels 20b have been formed in the wafer 10, the first laser beam LB1′ is applied to the wafer 10 while positioning its focused spot in the wafer 10 above the second layers of shield tunnels 20b, and the X-axis moving mechanism 4a, the Y-axis moving mechanism 4b, and the rotating mechanism are actuated to form third layers of shield tunnels 20c, each including a pore and a modified layer shielding the pore in surrounding relation thereto, over the second layers of shield tunnels 20b along the projected dicing lines 14 on the wafer 10, as illustrated in FIG. 6B. Laser processing conditions for forming the third layers of shield tunnels 20c in the wafer 10 are the same as the third processing conditions for forming the second layers of shield tunnels 20b.

According to the present modification, moreover, after the third layers of shield tunnels 20c have been formed in the wafer 10, the first laser beam LB1′ is applied to the wafer 10 while positioning its focused spot in the wafer 10 above the third layers of shield tunnels 20c, and the X-axis moving mechanism 4a, the Y-axis moving mechanism 4b, and the rotating mechanism are actuated to form forth layers of shield tunnels 20d, each including a pore and a modified layer shielding the pore in surrounding relation thereto, over the third layers of shield tunnels 20c and beneath the first layers of shield tunnels 20a, i.e., between the first layers of shield tunnels 20a and the third layers of shield tunnels 20c, along the projected dicing lines 14 on the wafer 10, as illustrated in FIG. 6C.

Laser processing conditions for forming the fourth layers of shield tunnels 20d in the wafer 10 are also the same as the third processing conditions for forming the second layers of shield tunnels 20b and the third layers of shield tunnels 20c. According to the present modification, when each of the fourth layers of shield tunnels 20d is formed beneath the corresponding one of the first layers of shield tunnels 20a in the wafer 10, the first layer of shield tunnels 20a is expanded, inducing cracks 112 in the wafer 10 along the projected dicing line 14 and exposing the cracks 112 on the face side 10a, as illustrated in FIG. 6C. The cracks 112 extend straight, rather than tortuously, along the projected dicing line 14.

In the first processing step, after each of the first layers of shield tunnels 20a has been formed, when shield tunnels are formed and stacked in the thicknesswise directions of the wafer 10 along each of the projected dicing lines 14, the number of stacked shield tunnels and the order in which those stacked shield tunnels are formed are not limited to the illustrated number and order, and may be selected as desired. For example, after the first layers of shield tunnels 20a have been formed, the fourth layers of shield tunnels 20d may be formed, and thereafter the third layers of shield tunnels 20c and the second layers of shield tunnels 20b may successively be formed. Alternatively, after the first layers of shield tunnels 20a have been formed, only the fourth layers of shield tunnels 20d may be formed before the first processing step comes to an end. However, since an energy loss caused when the first laser beam LB1′ is applied to form shield tunnels in the wafer 10 is made smaller by forming layers of shield tunnels successively upwardly in the wafer 10 in the thicknesswise directions thereof, it is preferable to form layers of shield tunnels successively upwardly in the wafer 10, as illustrated in FIGS. 6A through 6C.

Further, the height of layers of shield tunnels stacked in the wafer 10 in the first processing step can be adjusted by changing the third processing conditions, e.g., increasing the average power output of the laser beam. Specifically, according to the above modification, the four types of layers of shield tunnels 20a through 20d are stacked and interconnected in the thicknesswise directions of the wafer 10. However, a fewer number of stacked shield tunnels may be formed and interconnected in the thicknesswise directions of the wafer 10 by establishing laser processing conditions to increase the height of individual shield tunnels stacked in the wafer 10 beneath the first layers of shield tunnels 20a, e.g., by increasing the average power output of the laser beam.

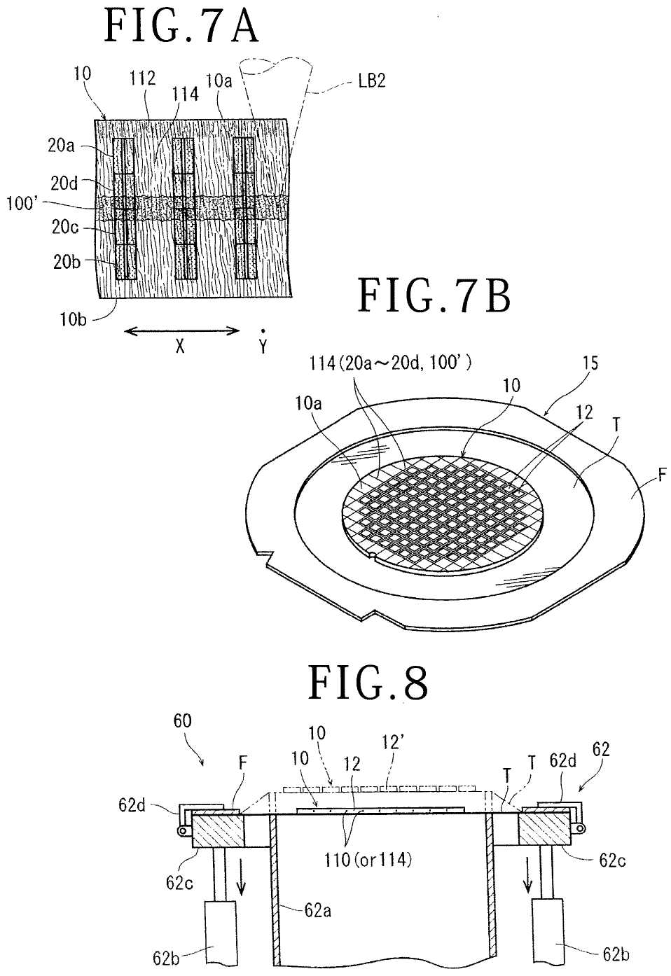

After the first through fourth layers of shield tunnels 20a through 20d have been formed in the wafer 10 in the thicknesswise directions in the modification of the first processing step, the second processing step is carried out. The focused spot of the second laser beam LB2 whose wavelength is transmittable through the wafer 10 and whose power output is stronger than those of the first layer beams LB1 and LB1′ applied in the first processing step is positioned in the wafer 10 along the projected dicing lines 14, e.g., at a substantially middle position in the thicknesswise directions of the wafer 10, as illustrated in FIG. 7A. Then, under the second processing conditions, the second laser beam LB2 is applied to the wafer 10, and the moving assembly 4 is actuated to move the wafer 10, forming modified layers 100′ in the wafer 10 along all the projected dicing lines 14 at intervals smaller than those of the shield tunnels 20a through 20d. When the modified layers 100′ are formed, the shield tunnels 20a through 20d are expanded, inducing cracks 114 in the wafer 10 along the projected dicing lines 14, as illustrated in FIGS. 7A and 7B. Since the cracks 114 start being developed from the modified layers 100′ and induced by the shield tunnels 20a through 20d, the cracks 114 extend straight, rather than tortuously, along the projected dicing lines 14.

According to the present modification, the second processing step is carried out after the shield tunnels 20a through 20d have been stacked in the wafer 10 in the thicknesswise directions thereof in the first processing step. Therefore, the cracks 114 extend toward the face side 10a and the reverse side 10b of the wafer 10 and are larger than the cracks 110 described with reference to FIG. 5B.

### Dividing Step

After the cracks 110 or 114 have been formed in the first processing step and the second processing step, a dividing step is carried out to apply external forces to the wafer 10 to divide the wafer 10 into individual device chips. External forces may be applied to the wafer 10 in any manners. For example, a dividing apparatus 60 illustrated in FIG. 8 may be used to carry out the dividing step.

The dividing apparatus 60 that is generally illustrated in FIG. 8 includes expanding means 62. The expanding means 62 includes an upstanding hollow cylindrical expanding drum 62a, a plurality of vertical air cylinders 62b disposed closely around the expanding drum 62a and spaced at intervals circumferentially around the expanding drum 62a, an annular holder 62c joined to upper ends of respective vertical piston rods of the air cylinders 62b, and a plurality of clamps 62d mounted on an outer circumferential edge portion of the annular holder 62c and spaced at intervals circumferentially around the annular holder 62c. The expanding drum 62a has an inside diameter larger than the diameter of the wafer 10 to be expanded by the dividing apparatus 60 and an outside diameter smaller than the inside diameter of the annular frame F. The annular holder 62c is substantially commensurate in diameter with the annular frame F and has a flat upper surface for supporting the annular frame F placed thereon.

As illustrated in FIG. 8, the air cylinders 62b move their piston rods to raise and lower the holder 62c between an upper reference position in which the upper surface of the holder 62c is of essentially the same height as an upper end of the expanding drum 62a and a lower expanding position in which the upper surface of the holder 62c is lower than the upper end of the expanding drum 62a. In FIG. 8, the wafer 10 held on the adhesive tape T is depicted as being raised and lowered together with the expanding drum 62a as indicated by solid lines and two-dot-and-dash lines for illustrative purposes. In actuality, however, the expanding drum 62a remains stationary and the holder 62c is raised and lowered with respect to the expanding drum 62a.

In operation, the dividing apparatus 60 expands the adhesive tape T that is affixed to the wafer 10, to apply external forces to the wafer 10. Specifically, the wafer 10 that has been processed in the first processing step and the second processing step has its face side 10a facing upwardly. The annular frame F affixed to the wafer 10 is placed on the upper surface of the holder 62c in the reference position and secured in place thereon by the clamps 62d. Then, the air cylinders 62b are actuated to lower their piston rods until the holder 62c goes down to the expanding position, pulling the tape T and the wafer 10 radially outwardly. At this time, external forces are applied to the wafer 10 radially outwardly, expanding the wafer 10 radially outwardly. The wafer 10 affixed to the adhesive tape T is now divided along the projected dicing lines 14 into individual device chips 12′. The device chips 12′ will thereafter be picked up by appropriate pick-up means, not depicted. The device chips 12′ thus picked up can be delivered to a subsequent step. Alternatively, the device chips 12′ can be stored in a suitable storage container.

As described above, the cracks 110 or 114 that are relatively large and extend straight, not tortuously, along the projected dicing lines 14 have been formed in the wafer 10 before the dividing step. Therefore, a load applied to the wafer 10 to apply external forces thereto in the dividing step may relatively be small in dividing the wafer 10 precisely into the individual device chips 12′ without causing the wafer 10 to break off chippings or fragments.

In the dividing step, external forces may be applied to the wafer 10 to divide the wafer 10 into individual device chips 12′ by any of various other means than the dividing apparatus 60. For example, the wafer 10 alone may be placed on an elastic pad, after which a hard roller may be pressed downwardly against the wafer 10 and rolled along each of the projected dicing lines 14 to apply external forces to the wafer 10, thereby dividing the wafer 10 into individual device chips 12′. Alternatively, a wedge-shaped presser, rather than the hard roller, may be pressed against the wafer 10 placed on the elastic pad along each of the projected dicing lines 14 to apply external forces to the wafer 10, thereby dividing the wafer 10 into individual device chips 12′.

According to the above embodiment, the wafer 10 includes a substrate of SiC. However, the wafer may include a substrate of any of various other materials, such as GaN, diamond, or sapphire, for example, and the present embodiment is applicable to wafers of such other materials while achieving the advantages described above. The laser processing conditions used in carrying out the first processing step and the second processing step in that case may appropriately be adjusted depending on the material and thickness among other properties of the wafer to be processed.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of processing a wafer with a plurality of devices formed in respective areas demarcated on a face side thereof by projected dicing lines, to thereby divide the wafer into individual device chips that include the respective devices, comprising:
a first processing step of forming shield tunnels, each including a pore and a modified layer surrounding the pore, in the wafer by applying a first laser beam having a wavelength transmittable through the wafer while positioning a focused spot of the first laser beam within the wafer in alignment with each of the projected dicing lines;
a second processing step of forming a modified layer in the wafer along each of the projected dicing lines by applying a second laser beam having a wavelength transmittable through the wafer and a power output stronger than that of the first laser beam while positioning a focused spot of the second laser beam within the wafer in alignment with each of the projected dicing lines, at intervals smaller than intervals at which the shield tunnels have been formed in the wafer, thereby inducing cracks in the wafer and exposing the cracks on the face side of the wafer along each of the projected dicing lines; and
a dividing step of dividing the wafer into individual device chips by applying an external force to the wafer.

2. The method of processing a wafer according to claim 1, wherein the first processing step includes forming a plurality of layers of shield tunnels stacked in thicknesswise directions of the wafer along each of the projected dicing lines.

3. The method of processing a wafer according to claim 1, wherein the first processing step and the second processing step include applying the first laser beam and the second laser beam, respectively, to the face side of the wafer.

4. The method of processing a wafer according to claim 1, wherein the wafer includes a substrate made of a material selected from a group consisting of SiC, GaN, diamond, and sapphire.
